(19) United States
(12) Patent Application Publication
(10) Pub. No.: US 2023/0061980 A1
(43) Pub. Date: Mar. 2, 2023

(54) OPTO-ELECTRIC HYBRID BOARD

(71) Applicant: NITTO DENKO CORPORATION, Osaka (JP)

(72) Inventors: Kazuaki SUZUKI, Osaka (JP); Naoyuki TANAKA, Osaka (JP); Naoto KONEGAWA, Osaka (JP)

(73) Assignee: NITTO DENKO CORPORATION, Osaka (JP)

(21) Appl. No.: 17/797,622

(22) PCT Filed: Feb. 12, 2021
(86) PCT No.: PCT/JP2021/005314

§ 371 Date: Aug. 4, 2022

(30) Foreign Application Priority Data
Feb. 12, 2020 (JP) 2020-021649

(51) Int. Cl. G02B 6/42; H05K 1/02

(52) U.S. Cl. CPC G02B 6/428; H05K 1/02

(57) ABSTRACT

An opto-electric hybrid board includes an optical waveguide, and an electric circuit board disposed on a one-side surface in the thickness direction of the optical waveguide. The electric circuit board includes a first terminal on which an optical element portion is mounted and a second terminal on which a driver element portion is mounted. The electric circuit board includes a metal supporting layer that overlaps the first terminal and the second terminal when the electric circuit board is projected in the thickness direction. The metal supporting layer has an opening portion that is located between the first terminal and the second terminal when the metal supporting layer is projected in the thickness direction.

The present invention relates to an opto-electric hybrid board.

### BACKGROUND ART

Conventionally, an opto-electric hybrid board sequentially including an optical waveguide, an electric circuit board, and a photonic device in the thickness direction has been known (for example, see Patent document 1 below).

In the opto-electric hybrid board of Patent document 1, the electric circuit board includes a metal supporting layer overlapping the photonic device in the thickness direction. Further, the electric circuit board includes a terminal for mounting various elements.

### CITATION LIST

### Patent Document

Patent Document 1: Japanese Unexamined Patent Publication No. 2019-039947

### SUMMARY OF THE INVENTION

### Problem to be Solved by the Invention

The optical element is mounted together with the adjacent driver element on the electric circuit board, and is electrically connected with the driver element and optically functions based on the driving of the driver element. However, the driver element generates a lot of heat when the driver element operates. When the heat is transmitted through the metal supporting layer to the optical element, the heat affects the optical element and reduces the function of the optical element.

Meanwhile, the metal supporting layer has a high thermal conductivity. Thus, it has been considered to remove the metal supporting layer from the opto-electric hybrid board. In the consideration, there is a disadvantage that the removal of the metal supporting layer facilitates the thermal storage in the driver element and reduces the function of the driver element. Further, the removal of the metal supporting layer reduces the stiffness of a part including the optical element. Thus, the positional accuracy of the optical element relative to the optical waveguide tends to decrease. As a result, there is another disadvantage that the optical connection reliability between the optical element and the optical waveguide decreases.

The present invention provides an opto-electric hybrid board that suppresses the reduction in the function of the driver element portion, has excellent connection reliability between the optical element portion and the optical waveguide, and, even when the driver element portion generates heat, suppresses the reduction in the function of the optical element portion by suppressing the transmission of the heat to the optical element portion.

### Means for Solving the Problem

The present invention [1] includes an opto-electric hybrid board comprising: an optical waveguide; and an electric circuit board disposed on a one-side surface in a thickness direction of the optical waveguide, the electric circuit board including a first terminal disposed on a one-side surface in the thickness direction of the electric circuit board, the first terminal being for mounting an optical element portion, and a second terminal disposed on the one-side surface in the thickness direction of the electric circuit board, the second terminal being for mounting a driver element portion separated from the optical element portion by an interval in a first direction, wherein the electric circuit board includes a metal supporting layer that overlaps the first terminal and the second terminal when the electric circuit board is projected in the thickness direction, and the metal supporting layer has a recess and/or a penetrating portion that are/is located between the first terminal and the second terminal when the metal supporting layer is projected in the thickness direction.

In the opto-electric hybrid board, the metal supporting layer overlaps the second terminal. Thus, the heat from the driver element portion mounted on the second terminal is dissipated to the metal supporting layer. Thus, the thermal storage is suppressed during the operation of the driver element portion, and the reduction in the function of the driver element portion caused by the thermal storage can be suppressed.

Further, the metal supporting layer overlaps the first terminal. Thus, the reduction in the stiffness of the part including the first terminal is suppressed. This can suppress the reduction in the connection reliability between the optical element portion and optical waveguide mounted on the first terminal.

Further, in the opto-electric hybrid board, the recess and/or penetrating portion of the metal supporting layer suppress/suppresses the direct transmission of the heat to the optical element portion and thus can suppress the reduction in the function of the optical element portion when the driver element portion mounted on the second terminal operates and generates heat.

The present invention [2] includes the opto-electric hybrid board described in [1], wherein the recess and/or the penetrating portion are/is longer than each of the optical element portion and the driver element portion in an orthogonal direction orthogonal to the thickness direction and the first direction.

In the opto-electric hybrid board, the recess and/or the penetrating portion are/is longer than each of the optical element portion and the driver element portion. This can effectively suppress the transmission of the heat of the driver element portion to the optical element portion.

The present invention [3] includes the opto-electric hybrid board described in [1] or [2], wherein the recess and/or the penetrating portion are/is filled with a part of the optical waveguide.

In the opto-electric hybrid board, a part of the optical waveguide portion fills the recess and/or the penetrating portion. The optical waveguide portion has a lower thermal conductivity than that of the metal supporting layer. Thus, the transmission of the heat of the driver element portion to the optical element portion can effectively be suppressed.

### Effects of the Invention

The opto-electric hybrid board of the present invention suppresses the reduction in the function of the driver element portion, has excellent connection reliability between the optical element portion and the optical waveguide, and, even when the driver element portion generates heat, suppresses the transmission of the heat to the optical element portion and thus can suppress the reduction in the function of the optical element portion.

### BRIEF DESCRIPTION OF THE DRAWINGS

FIG. 1A and FIG. 1B show an opto-electric hybrid board. FIG. 1A is a plan view of the opto-electric hybrid board. FIG. 1B is a plan view of the opto-electric hybrid board, omitting an insulating base layer, a conductive layer, and an insulating cover layer therefrom.

FIG. 2 is a cross-sectional side view of the opto-electric hybrid board of FIG. 1A and FIG. 1B, taken along line X-X.

FIG. 3A to FIG. 3D illustrate the steps of producing the opto-electric hybrid board of FIG. 2.

FIG. 3A illustrates a step of preparing a metal sheet. FIG. 3B illustrates a step of forming an insulating base layer, a conductive layer, and an insulating cover layer. FIG. 3C illustrates a step of forming the opening portion. FIG. 3D illustrates a step of forming an optical waveguide.

FIG. 4 is a plan view of a variation of the opto-electric hybrid board shown in FIG. 1B (where the opening portion and the first auxiliary opening portion form an approximate C shape).

FIG. 5 is a plan view of a variation of the opto-electric hybrid board shown in FIG. 1B (where the opening portion and the second auxiliary opening portion form an approximate cross shape).

FIG. 6A and FIG. 6B are plan views of variations of the opto-electric hybrid board shown in FIG. 1B. FIG. 6A shows a variation in which the notched opening portion is notched from a one end surface in the width direction of the metal supporting layer. FIG. 6B shows a variation in which the notched opening portion is notched from the other end surface in the width direction of the metal supporting layer.

FIG. 7 is a plan view of a variation of the opto-electric hybrid board shown in FIG. 1B (where the opening portion penetrates the metal supporting layer in the width direction in the plan view).

FIG. 8A to FIG. 8C show variations of the dimensions and shape of the opening portion. FIG. 8A shows a variation in which the opening portion has a length identical to the length of each of the light-emitting element and the drive integrated circuit. FIG. 8B shows a variation in which the opening portion has a smaller length than the length of each of the light-emitting element and the drive integrated circuit. FIG. 8C shows a variation in which the opening portion has an approximately circular shape.

FIG. 9 is a cross-sectional view of a variation of the opto-electric hybrid board shown in FIG. 2 (where the opening portion forms a void).

FIG. 10A and FIG. 10B are cross-sectional views of variations of the opto-electric hybrid board (each including a recess) shown in FIG. 2. FIG. 10A shows a variation in which the recess is recessed from a one-side surface in the thickness direction of the metal supporting layer. FIG. 10B shows a variation in which the recess is recessed from the other-side surface in the thickness direction of the metal supporting layer.

FIG. 11 is a plan view of a variation of the opto-electric hybrid board (including two opening portions) shown in FIG. 1B.

### DESCRIPTION OF THE EMBODIMENTS

### One Embodiment

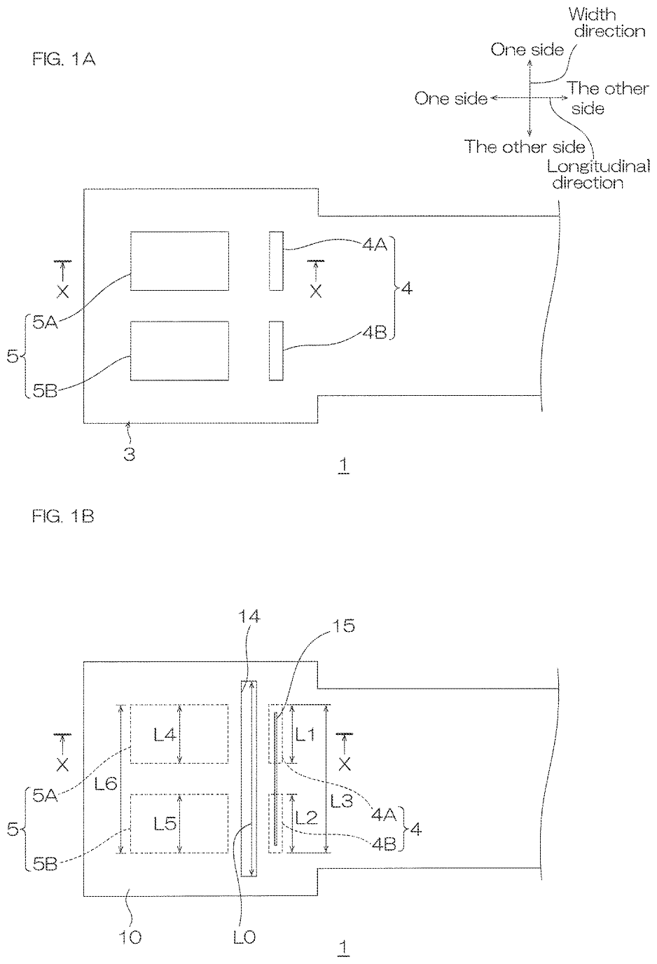

One embodiment of the opto-electric hybrid board of the present invention is described with reference to FIG. 1A to FIG. 3D. To clarify the disposition of an opening portion 14 and an optical connection opening portion 15 of a metal supporting layer 10 and an optical element portion 4 and a driver element portion 5 (described below) and the shapes thereof, FIG. 1B excludes an insulating base layer 11, a conductive layer 12, and an insulating cover layer 13 (described below) therefrom and shows the optical element portion 4 and the driver element portion 5 as dashed lines.

An opto-electric hybrid board 1 has a predetermined thickness, and has an approximately flat belt shape extending in a longitudinal direction as an example of a first direction. In details, the opto-electric hybrid board 1 has a one end portion, an intermediate portion, and the other end portion in the longitudinal direction, and the one end portion is wider than each of the intermediate portion and the other end portion (the one end portion has a larger length than that of each of the intermediate portion and the other end portion in a width direction orthogonal to a thickness direction and a longitudinal direction).

The opto-electric hybrid board 1 includes an optical waveguide 2, an electric circuit board 3, the optical element portion 4, and the driver element portion 5.

The optical waveguide 2 is the other side part in the thickness direction of the opto-electric hybrid board 1. The optical waveguide 2 has an outer shape identical to that of the opto-electric hybrid board 1. In other words, the optical waveguide 2 has a shape extending along the longitudinal direction. The optical waveguide 2 includes an under-cladding layer 6, a core layer 7, and an over-cladding layer 8.

The under-cladding layer 6 has a shape identical to the outer shape of the optical waveguide 2 in the plan view.

The core layer 7 is disposed on an intermediate portion in the width direction of the other-side surface in the thickness direction of the under-cladding layer 6. The core layer 7 has a smaller width than the width of the under-cladding layer 6 in the plan view. Although not illustrated, a plurality (for example, eight) of the core layers 7 are disposed in parallel, being separated from each other by an interval in the width direction). The core layers 7 are optically connected with the light-emitting element 4A and the light-receiving element 4B (both described below), respectively.

The over-cladding layer 8 is disposed on the other-side surface in the thickness direction of the under-cladding layer 6 to cover the core layer 7. The over-cladding layer 8 has a shape identical to an outer shape of the under-cladding layer 6 in the plan view. Specifically, the over-cladding layer 8 is disposed on the other-side surface in the thickness direction of the core layer 7 and both side surfaces in the width direction of the core layer 7, and on the other-side surface in the thickness direction of the under-cladding layer 6 at both outsides in the width direction of the core layer 7.

A mirror 9 is formed in the one end portion in the longitudinal direction of the core layer 7.

Examples of the material of the optical waveguide 2 include transparent materials such as epoxy resins. The core layer 7 has a higher refractive index than each of the refractive index of the under-cladding layer 6 and the refractive index of the over-cladding layer 8. The optical waveguide 2 has a thickness of, for example, 20 μm or more, and, for example, 200 μm or less.

The electric circuit board 3 is disposed on a one-side surface in the thickness direction of the optical waveguide 2. The electric circuit board 3 includes the metal supporting layer 10, the insulating base layer 11, the conductive layer 12, and the insulating cover layer 13.

The metal supporting layer 10 has an outer shape identical to that of the optical waveguide 2 in the plan view. A one-side surface in the thickness direction of the metal supporting layer 10 is in contact with the under-cladding layer 6. The metal supporting layer 10 has the opening portion 14 as an example of a penetrating portion, and an optical connection opening portion 15.

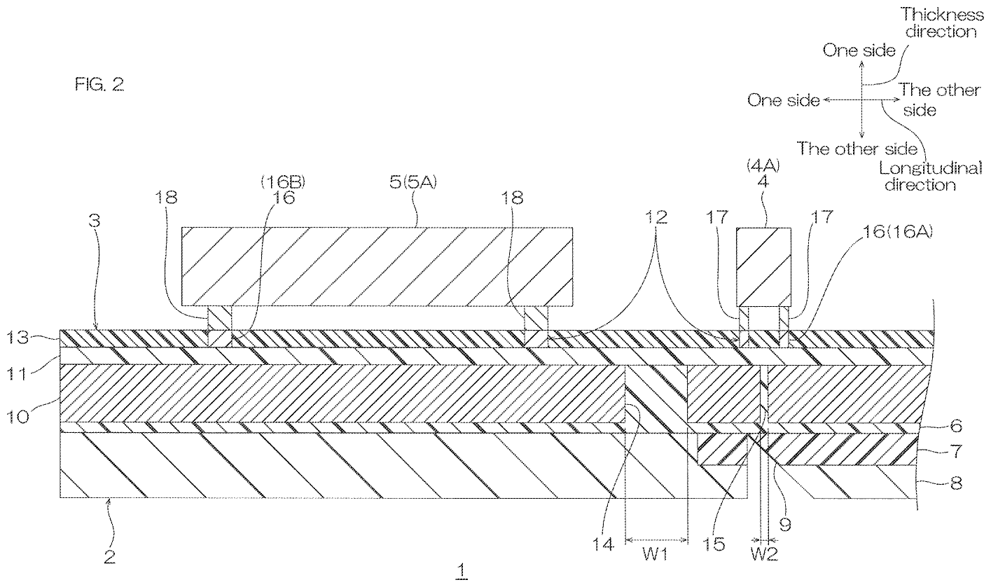

As illustrated in FIG. 1B and FIG. 2, the opening portion 14 is a through-hole penetrating the metal supporting layer 10 in the thickness direction. The opening portion 14 is disposed in the one end portion in the longitudinal direction of the electric circuit board 3. In the plan view, the opening portion 14 has an approximately straight line shape (narrow rectangular shape) extending along the width direction.

The metal supporting layer 10 has an inside surface defining the opening portion 14 and being in contact with the under-cladding layer 6. The opening portion 14 is filled with a part of the under-cladding layer 6 of the optical waveguide 2 described below. Thus, no void (no gap) substantially exists in the opening portion 14.

The opening portion 14 has a length W1 of, for example, 50 μm or more, preferably 75 μm or more, and, for example, 200 μm or less, preferably 125 μm or less in the longitudinal direction.

Where the length W1 in the longitudinal direction of the opening portion 14 is the above-described lower limit or more, even when the driver element portion 5 generates heat, the transmission of the heat to the optical element portion 4 can surely be suppressed. When the length W1 in the longitudinal direction of the opening portion 14 is the above-described upper limit or less, the stiffness of the one end portion in the longitudinal direction of the opto-electric hybrid board 1 is ensured.

The optical connection opening portion 15 is a through-hole penetrating the metal supporting layer 10 in the thickness direction. The optical connection opening portion 15 is disposed in the electric circuit board 3, corresponding to the optical element portion 4 described below. In the plan view, the optical connection opening portion 15 has a slit shape extending along the width direction.

The metal supporting layer 10 has an inside surface defining the optical connection opening portion 15 and being in contact with the under-cladding layer 6. The optical connection opening portion 15 is filled with a part of the under-cladding layer 6 of the optical waveguide 2. Thus, no void (no gap) substantially exists in the optical connection opening portion 15.

The optical connection opening portion 15 has a length W2 of, for example, 50 μm or more, preferably 100 μm or more, and, for example, 200 μm or less, preferably 150 μm or less in the longitudinal direction.

Examples of the material of the metal supporting layer 10 include metals such as stainless steels, 42 alloys, aluminum, copper-beryllium, phosphor bronze, copper, silver, nickel, chromium, titanium, tantalum, platinum, and gold. To achieve excellent thermal conductivity, copper and a stainless steel are preferable. The metal supporting layer 10 has a thickness of, for example, 3 μm or more, preferably 10 μm or more, and, for example, 100 μm or less, preferably 50 μm or less.

As illustrated in FIG. 2, the insulating base layer 11 is disposed on the one-side surface in the thickness direction of the metal supporting layer 10. The insulating base layer 11 has an outer shape identical to that of the metal supporting layer 10 in the plan view. The other-side surface in the thickness direction of each of the opening portion 14 and the optical connection opening portion 15 is in contact with the under-cladding layer 6 on the insulating base layer 11. Examples of the material of the insulating base layer 11 include resins such as polyimide. The insulating base layer 11 has a thickness of, for example, 5 μm or more, and, for example, 50 μm or less, and, in view of thermal dissipation, preferably 40 μm or less, more preferably 30 μm or less.

The conductive layer 12 is disposed on a one-side surface in the thickness direction of the insulating base layer 11. The conductive layer 12 includes the terminal portion 16 and wire (not illustrated). The terminal portion 16 include first terminals 16A corresponding to the optical element portion 4 described below, first terminals 16B corresponding to the driver element portion 5 described below, and third terminals (neither of them illustrated) corresponding to a power-supply device and an external board. The wire not illustrated continues to the terminal portion 16. Specifically, the wire not illustrated couples the first terminal 16A corresponding to the light-emitting element 4A with the second terminal 16B corresponding to a drive integrated circuit 5A. Further, the wire not illustrated couples the first terminal 16A corresponding to the light-receiving element 4B with the second terminal 16B corresponding to the impedance converting amplifier circuit 5B. The optical element portion 4 is mounted on the first terminals 16A. The driver element portion 5 is mounted on the second terminals 16B.

Examples of the material of the conductive layer 12 include conductors such as copper. The conductive layer 12 has a thickness of, for example, 3 μm or more, and, for example, 20 μm or less.

The insulating cover layer 13 is disposed on the one-side surface in the thickness direction of the insulating base layer 11 to cover the wire not illustrated. The insulating cover layer 13 exposes the terminal portion 16. Examples of the material of the insulating cover layer 13 include resins such as polyimide. The insulating cover layer 13 has a thickness of, for example, 5 μm or more, and, for example, 50 μm or less, and, in view of thermal dissipation, preferably 40 μm or less, more preferably 30 μm or less.

As illustrated in FIG. 1A to FIG. 2, the optical element portion 4 is disposed in the other-side part of the one end portion in the longitudinal direction of the opto-electric hybrid board 1. A plurality (two) of the optical element portions 4 is disposed in the width direction, being separated from each other by an interval. The optical element portions 4 include, for example, the light-emitting element 4A and the light-receiving element 4B.

The light-emitting element 4A converts electricity to light. The light-emitting element 4A has a light emitting aperture (not illustrated) disposed on the other-side surface in the thickness direction of the light-emitting element 4A. Specific examples of the light-emitting element 4A include a vertical-external-cavity surface-emitting-laser (VECSEL).

The light-receiving element 4B faces the light-emitting element 4A, is disposed at the other side in the width direction of the light-emitting element 4A, and is separated from the light-emitting element 4A by an interval. The light-receiving element 4B converts light into electricity. The light-receiving element 4B has a light receiving aperture (not illustrated) disposed on the other surface in the thickness direction of the light-receiving element 4B. Specific examples of the light-receiving element 4B include a photodiode (PD).

Both of the light-emitting element 4A and the light-receiving element 4B overlap the optical connection opening portion 15 in the plan view. Further, the light-emitting element 4A and the light-receiving element 4B are disposed at a one side in the longitudinal direction of the opening portion 14, being separated from each other by an interval.

Each of the light-emitting element 4A and the light-receiving element 4B has an approximately rectangular board shape. Each of the light-emitting element 4A and the light-receiving element 4B includes a first bump 17 on the other-side surface in the thickness direction of each of the light-emitting element 4A and the light-receiving element 4B. The first bump 17 overlaps the first terminal 16A and is coupled with the first terminal 16A to electrically be connected with the conductive layer 12.

The driver element portion 5 is disposed in a one-side part of the one end portion in the longitudinal direction of the opto-electric hybrid board 1. The driver element portion 5 faces the optical element portion 4, is disposed at the one side in the longitudinal direction of the optical element portion 4, and is separated from the optical element portion 4 by an interval. In the plan view, the driver element portion 5 is disposed at the one side in the longitudinal direction of the opening portion 14, being separated from the opening portion 14 by an interval. In this manner, the driver element portion 5 is disposed at an opposite side to the optical element portion 4 with respect to the opening portion 14 in the longitudinal direction. In other words, the optical element portion 4 and the driver element portion 5 hold the opening portion 14 therebetween in the longitudinal direction. In other words, the first terminals 16A and the second terminals 16B hold the opening portion 14 therebetween in the longitudinal direction.

A plurality (two) of the driver element portions 5 is disposed in the width direction, being separated from each other by an interval. The driver element portions 5 include, for example, the drive integrated circuit 5A and an impedance converting amplifier circuit 5B.

The drive integrated circuit 5A drives the light-emitting element 4A by the input of a power source current (electricity) from the first terminal 16A. At the time, the drive integrated circuit 5A is allowed to generate a lot of heat.

The impedance converting amplifier circuit 5B faces the drive integrated circuit 5A, is disposed at the other side in the width direction of the drive integrated circuit 5A, and is separated from the drive integrated circuit 5A by an interval. The impedance converting amplifier circuit 5B amplifies the electricity (signal current) from the light-receiving element 4B. At the time, the impedance converting amplifier circuit 5B is allowed to generate a lot of heat.

Each of the drive integrated circuit 5A and the impedance converting amplifier circuit 5B has an approximately rectangular board shape. Each of the drive integrated circuit 5A and the impedance converting amplifier circuit 5B includes a second bump 18 on the other-side surface in the thickness direction of each of the drive integrated circuit 5A and the impedance converting amplifier circuit 5B. The second bump 18 overlaps the second terminal 16B and is coupled with the second terminal 16B to electrically be connected with the conductive layer 12.

As illustrated in FIG. 1B, the opening portion 14 is longer than each of the optical element portion 4 and the driver element portion 5 in the width direction.

Specifically, a length L0 of the opening portion 14 is larger than each of the lengths L1 and L2 of the optical element portions 4. In detail, the length L0 of the opening portion 14 is larger than the length L1 of the light-emitting element 4A, and larger than the length L2 of the light-receiving element 4B in the width direction. The length L0 of the opening portion 14 is larger than a length L3 between one edge in the width direction of the light-emitting element 4A and the other edge in the width direction of the light-receiving element 4B in the width direction. A ratio (L0/L3) of the length L0 of the opening portion 14 to the above-described length L3 is, for example, more than 1.0, preferably 1.2 or more, and, for example, 2.0 or less, preferably 1.8 or less. When the ratio (L0/L3) is the above-described lower limit or more, a path through which the heat generated in the driver element portion 5 is transmitted to the optical element portion 4 is made sufficiently long. This can further suppress the reduction in the function of the optical element portion 4. When the ratio (L0/L3) is the above-described upper limit or less, the excellent stiffness of the one end portion in the longitudinal direction of the opto-electric hybrid board 1 can be ensured.

The length L0 of the opening portion 14 is larger than each of lengths L4 and L5 of the driver element portions 5 in the width direction. In detail, in the width direction, the length L0 of the opening portion 14 is larger than the length L4 of the drive integrated circuit 5A, and larger than the length L5 of the impedance converting amplifier circuit 5B. Further, in the width direction, the length L0 of the opening portion 14 is larger than a length L6 between one edge in the width direction of the drive integrated circuit 5A and the other edge in the width direction of the impedance converting amplifier circuit 5B. A ratio (L0/L6) of the length L0 of the opening portion 14 to the above-described length L6 is, for example, more than 1.0, preferably 1.2 or more, and, for example, 2.0 or less, preferably 1.8 or less. When the ratio (L0/L6) is the above-described lower limit or more, a path through which the heat generated in the driver element portion 5 is transmitted to the optical element portion 4 is made sufficiently long. This can further suppress the reduction in the function of the optical element portion 4. When the ratio (L0/L6) is the above-described upper limit or less, the excellent stiffness of the one end portion in the longitudinal direction of the opto-electric hybrid board 1 can be ensured.

Subsequently, a method of producing the opto-electric hybrid board 1 is described.

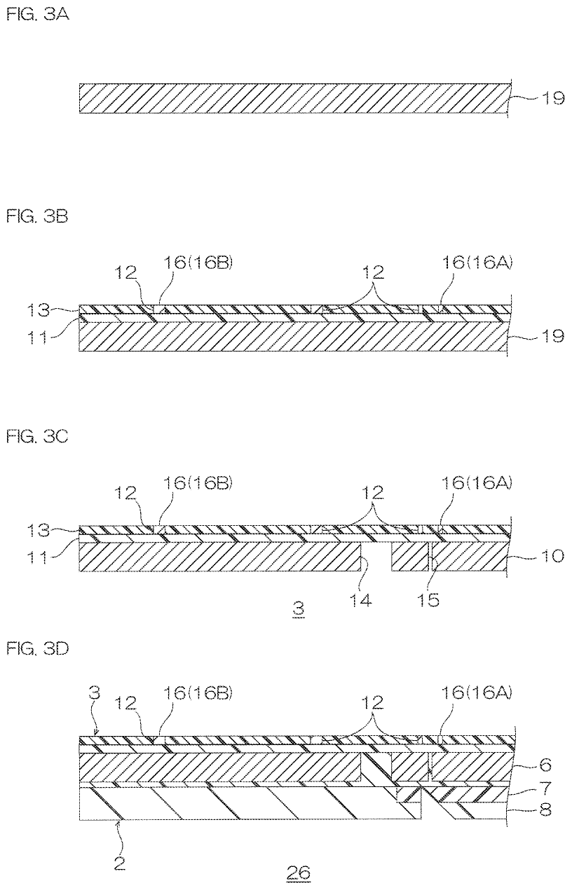

As illustrated in FIG. 3A, in this method, a metal sheet 19 is prepared first. The metal sheet 19 is a sheet from which the metal supporting layer 10 is formed.

As illustrated in FIG. 3B, in this method, the insulating base layer 11 is formed on the one-side surface in the thickness direction of the metal supporting layer 10 next. For example, a photosensitive resin composition containing a resin is applied to the whole of the one-side surface in the thickness direction of the metal sheet 19 to form a photosensitive film, and the formed film is subjected to photolithography to form the insulating base layer 11.

Next, in this method, the conductive layer 12 is formed on the one-side surface in the thickness direction of the insulating base layer 11. Examples of the method of forming the conductive layer 12 include an additive method and a subtractive method.

Next, in this method, the insulating cover layer 13 is formed on the one-side surface in the thickness direction of the insulating base layer 11 to cover the wire not illustrated. For example, a photosensitive resin composition containing a resin is applied to the whole of the one-side surfaces in the thickness direction of the insulating base layer 11 and the conductive layer 12 to form a photosensitive film, and the formed film is subjected to photolithography to form the insulating cover layer 13.

Thereafter, as illustrated in FIG. 3C, the outer shape of the metal sheet 19 is processed by, for example, etching to form the metal supporting layer 10 having the opening portion 14 and the optical connection opening portion 15.

In this manner, the electric circuit board 3 is produced.

Thereafter, as illustrated in FIG. 3D, the optical waveguide 2 is produced to be incorporated in the other-side surface in the thickness direction of the electric circuit board 3.

For example, a photosensitive resin composition containing the material of the under-cladding layer 6 is applied on the other-side surface in the thickness direction of the electric circuit board 3 to form a photosensitive film. Thereafter, the photosensitive film is subjected to photolithography to form the under-cladding layer 6.

Subsequently, a photosensitive resin composition containing the material of the core layer 7 is applied to the other-side surface in the thickness direction of the under-cladding layer 6 to form a photosensitive film. Thereafter, the photosensitive film is subjected to photolithography to form the core layer 7.

Thereafter, a photosensitive resin composition containing the material of the over-cladding layer 8 is applied to the other-side surfaces in the thickness direction of the under-cladding layer 6 and the core layer 7 to form a photosensitive film. Thereafter, the photosensitive film is subjected to photolithography to form the over-cladding layer 8.

In this manner, an opto-electric hybrid board 26 for mounting element portions that sequentially includes the optical waveguide 2 and the electric circuit board 3 toward the one side in the thickness direction is produced.

The optical element portion 4 and the driver element portion 5 are not mounted on the opto-electric hybrid board 26 for mounting element portions yet. However, the opto-electric hybrid board 26 for mounting element portions can be distributed as a single component and is an industrially-available device. The opto-electric hybrid board 26 for mounting element portions includes the first terminals 16A and the second terminals 16B, and is an example of the opto-electric hybrid board of the present invention.

Subsequently, as illustrated in FIG. 2, the optical element portions 4 and the driver element portions 5 are mounted on the one end portion in the longitudinal direction of the electric circuit board 3. The bump not illustrated and consisting of a metal that can be molten, such as gold or a solder, is disposed on the one-side surface in the thickness direction of the terminal portion 16. Using the bumps, the first bump 17 and first terminal 16A of the optical element portion 4 are electrically connected to each other, and the second bump 18 and second terminal 16B of the driver element portion 5 are electrically connected to each other. Further, the power-supply device and the external board (neither of them illustrated) are electrically connected to the third terminals not illustrated.

In this manner, the opto-electric hybrid board 1 including the optical waveguide 2, the electric circuit board 3, the optical element portion 4, and the driver element portion 5 is produced.

A power source current supplied from the power-supply device (not illustrated) is input to the drive integrated circuit 5A. Then, the drive integrated circuit 5A drives the light-emitting element 4A. The light-emitting element 4A emits light to the mirror 9. The optical waveguide 2 transmits the light to the other edge in the longitudinal direction of the optical waveguide 2.

On the other hand, another light is input from the other edge in the longitudinal direction of the optical waveguide 2 through the mirror 9 to the light-receiving element 4B. The light-receiving element 4B generates a weak electricity (signal current). The impedance converting amplifier circuit 5B amplifies the electricity (signal current). The electricity is input to the external board.

### Operations and Effects of One Embodiment

The metal supporting layer 10 overlaps the second terminals 16B in the opto-electric hybrid board 1. Thus, when the driver element portion 5 is mounted on the second terminals 16B, the heat from the driver element portion 5 is dissipated to the metal supporting layer 10. Thus, when the driver element portion 5 operates, the thermal storage in the driver element portion 5 is suppressed and the reduction in the function caused by the thermal storage is suppressed.

Further, the metal supporting layer 10 overlaps the first terminals 16A. Thus, when the optical element portion 4 is mounted on the first terminals 16A, the reduction in the stiffness of the part including the optical element portion 4 is suppressed. Thus, the reduction in the optical connection reliability between the optical element portion 4 and the optical waveguide 2 is suppressed.

Furthermore, when the driver element portion 5 operates and generates heat, the opening portion 14 of the metal supporting layer 10 suppresses the direct transmission of the heat to the optical element portion 4 in the opto-electric hybrid board 1 and can suppress the reduction in the function of the optical element portion 4.

In the opto-electric hybrid board 1, the opening portion 14 is longer than each of the optical element portion 4 and the driver element portion 5. This can effectively suppress the transmission of the heat of the driver element portion 5 to the optical element portion 4.

The opening portion 14 is filled with a part of the under-cladding layer 6 of the optical waveguide 2 in the opto-electric hybrid board 1, and the optical waveguide 2 has a lower thermal conductivity than that of the metal supporting layer 10. This can effectively suppress the transmission of the heat of the driver element portion 5 to the optical element portion 4.

### <Variations>

In each of the following variations, the same members and steps as in the above-described embodiment are given the same numerical references and the detailed descriptions thereof are omitted. Further, the variations can have the same operations and effects as those of the embodiment unless especially described otherwise. Furthermore, the embodiment and the variations can appropriately be combined.

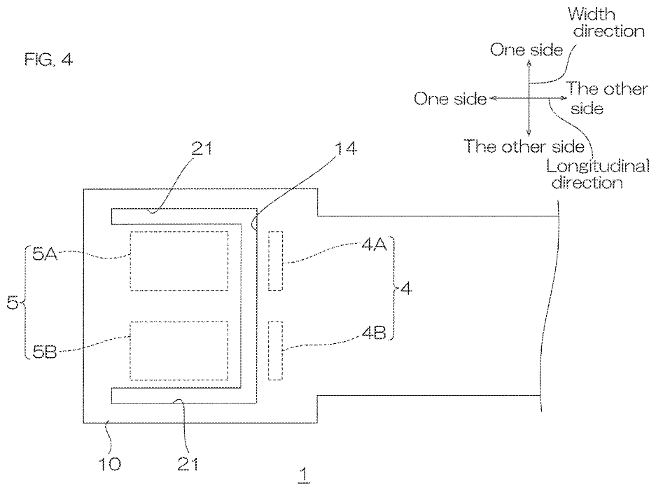

In the variation illustrated in FIG. 4, the metal supporting layer 10 further includes first auxiliary opening portions 21 communicated with the opening portion 14.

The first auxiliary opening portions 21 extend from both ends in the width direction of the opening portion 14 toward the one side in the longitudinal direction. When being projected in the width direction, each of the two first auxiliary opening portions 21 overlaps the driver element portion 5. In this manner, the opening portion 14 and the two first auxiliary opening portions 21 form an approximate C shape (U shape) being open toward the one side in the longitudinal direction in the plan view.

In the variation illustrated in FIG. 4, the first auxiliary opening portions 21 make the path through which the heat of the driver element portion 5 is transmitted to the optical element portion 4 further longer. In this manner, the transmission of the heat of the driver element portion 5 to the optical element portion 4 can further more effectively be suppressed.

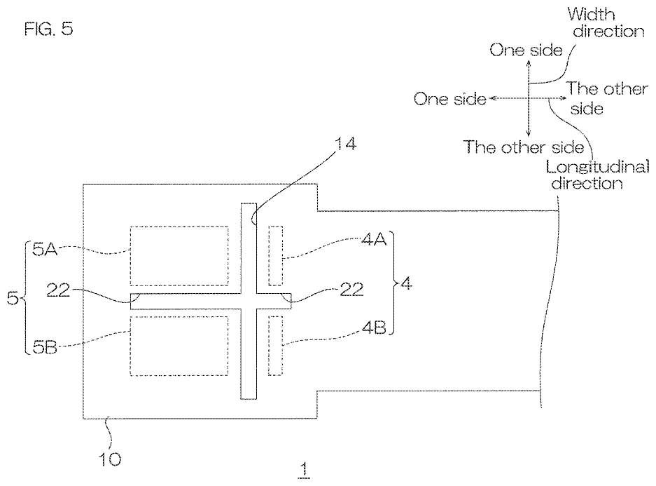

In the variation illustrated in FIG. 5, the metal supporting layer 10 includes second auxiliary opening portions 22 communicated with the opening portion 14.

The second auxiliary opening portions 22 extend from an intermediate portion in the width direction of the opening portion 14 toward both sides in the longitudinal direction. When being projected in the width direction, the two second auxiliary opening portions 22 overlap the driver element portion 5 and the optical element portion 4, respectively. In this manner, the opening portion 14 and the two second auxiliary opening portions 22 form a plus (cross) shape in the plan view.

In the variation illustrated in FIG. 5, the path through which the heat of the driver element portion 5 is transmitted to the optical element portion 4 is made further longer. This can further effectively suppress the transmission of the heat of the drive integrated circuit 5A to the light-receiving element 4B. The path through which the heat of the impedance converting amplifier circuit 5B is transmitted to the light-emitting element 4A is made further longer. This can further effectively suppress the transmission of the heat of the impedance converting amplifier circuit 5B to the light-emitting element 4A.

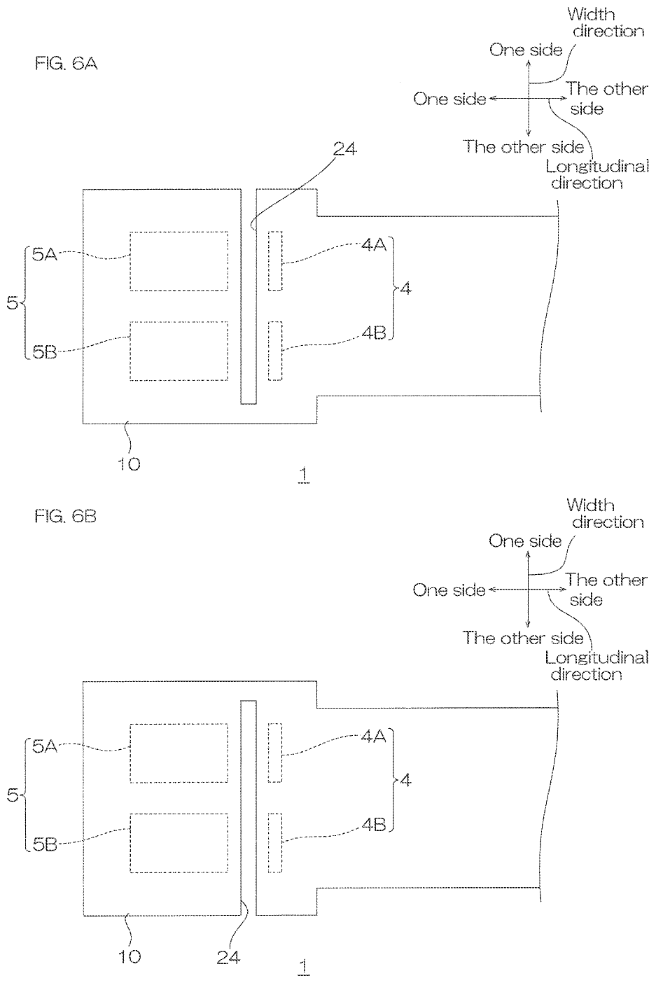

Instead of the opening portion 14, the variation illustrated in FIG. 6A and FIG. 6B has a notched opening portion 24 notched from an end surface in the width direction of the metal supporting layer 10 toward the inside.

In the variation illustrated in FIG. 6A, the notched opening portion 24 is notched from the one end surface in the width direction of the metal supporting layer 10 toward the other side in the width direction.

In the variation illustrated in FIG. 6B, the notched opening portion 24 is notched from the other end surface in the width direction of the metal supporting layer 10 toward the one side in the width direction.

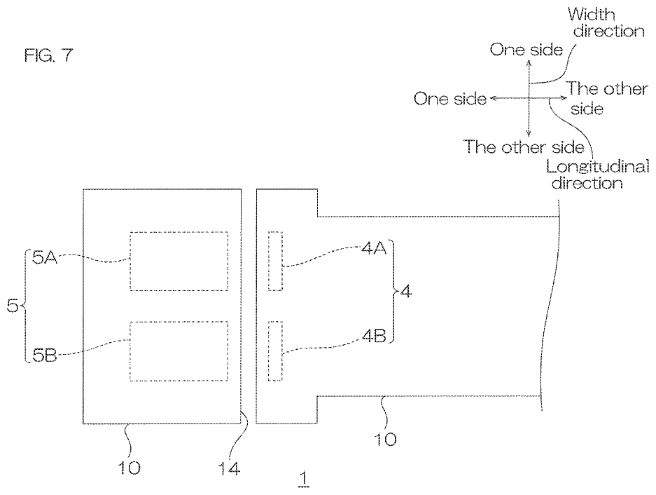

In the variation illustrated in FIG. 7, the opening portion 14 penetrates the metal supporting layer 10 in the width direction in the plan view. The opening portion 14 extends from the one edge in the width direction of the metal supporting layer 10 toward the other edge. In this manner, the opening portion 14 divides the metal supporting layer 10 in the longitudinal direction into the metal supporting layer 10 in which the optical element portion 4 is located and the metal supporting layer 10 in which the driver element portion 5 is located.

In the variation illustrated in FIG. 7, the flow of the heat from the part of the metal supporting layer 10 corresponding to the driver element portion 5 to the part of the metal supporting layer 10 corresponding to the optical element portion 4 is substantially disconnected. Thus, the transmission of the heat of the drive integrated circuit 5A to the light-receiving element 4B is particularly effectively suppressed.

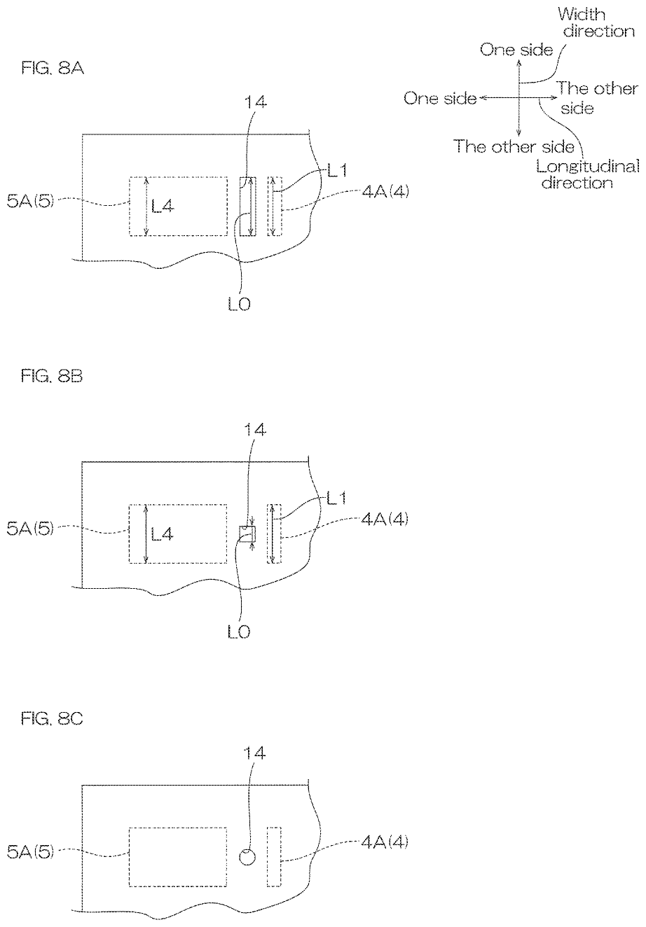

In the variation illustrated in FIG. 8A, the length L0 of the opening portion 14 is identical to each of the length L1 of the light-emitting element 4A and the length L4 of the drive integrated circuit 5A.

In the variation illustrated in FIG. 8B, the length L0 of the opening portion 14 is smaller than each of the length L1 of the light-emitting element 4A and the length L4 of the drive integrated circuit 5A.

The shape of the opening portion 14 in the plan view is not especially limited. For example, as illustrated in FIG. 8C, the opening portion 14 has an approximately circular shape in the plan view.

In the variations illustrated in FIG. 8A to FIG. 8C, the shape and disposition of the opening portion 14 relative to the light-receiving element 4B and the impedance converting amplifier circuit 5B are identical to the above-described shape and disposition of the opening portion 14 relative to the light-emitting element 4A and the drive integrated circuit 5A.

Although not illustrated, the optical element portion 4 may include only one of the light-emitting element 4A and the light-receiving element 4B. The driver element portion 5 may include only one of the drive integrated circuit 5A and the impedance converting amplifier circuit 5B.

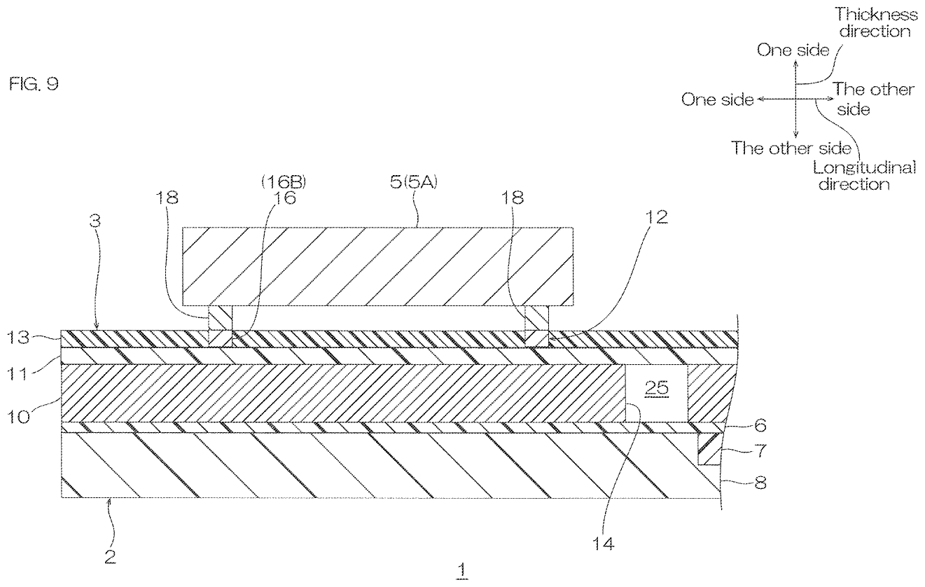

In the variation illustrated in FIG. 9, the opening portion 14 forms a void 25. In other words, the inside of the opening portion 14 is not filled with the under-cladding layer 6.

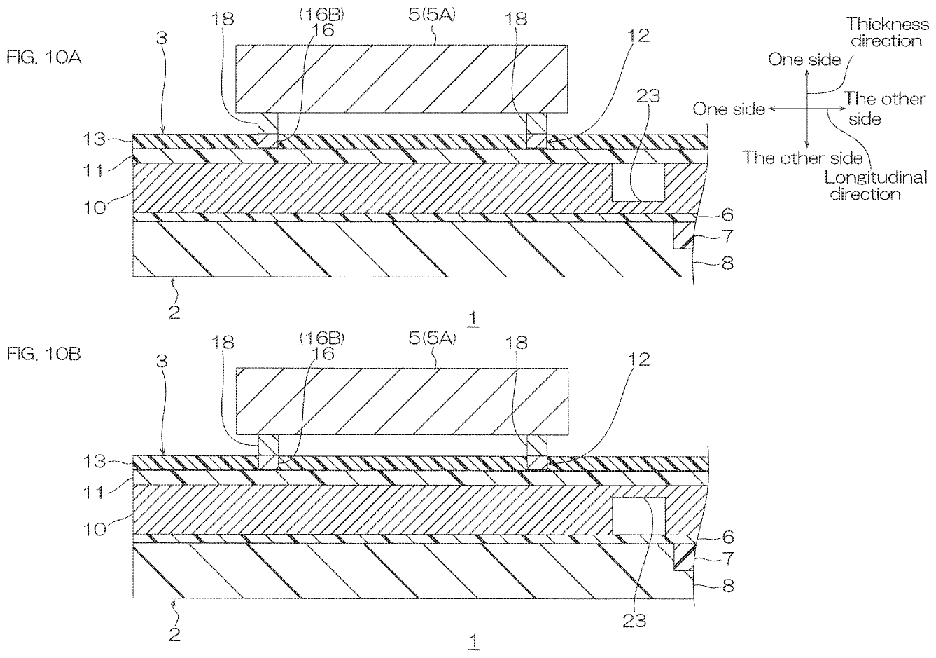

As illustrated in FIG. 10A and FIG. 10B, a recess 23 extends from one of a one-side surface and the other-side surface in the thickness direction of the metal supporting layer 10 to an intermediate part of the thickness direction of the metal supporting layer 10.

In the variation illustrated in FIG. 10A, the recess 23 extends from the one-side surface in the thickness direction of the metal supporting layer 10 to an intermediate part in the thickness direction of the metal supporting layer 10 toward the other side in the thickness direction.

In the variation illustrated in FIG. 10B, the recess 23 extends from the other-side surface in the thickness direction of the metal supporting layer 10 to an intermediate part in the thickness direction of the metal supporting layer 10 toward the one side in the thickness direction.

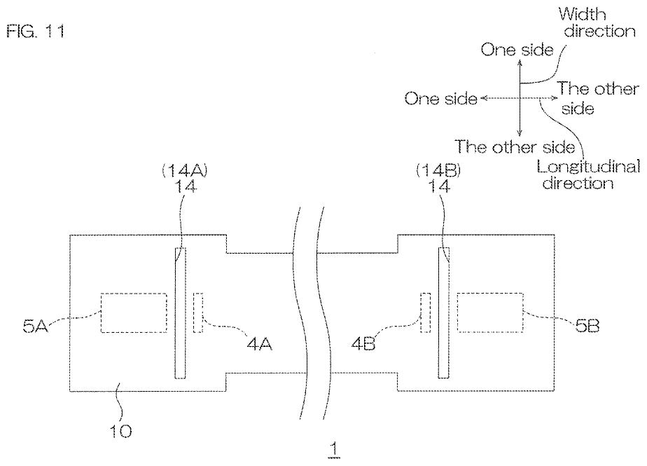

As illustrated in FIG. 11, two opening portions 14 can be disposed in a one end portion and the other end portion in the longitudinal direction of the opto-electric hybrid board 1, respectively. The two opening portions 14 are a first opening portion 14A and a second opening portion 14B. The first opening portion 14A is disposed in the one end portion in the longitudinal direction of the opto-electric hybrid board 1. The second opening portion 14B is disposed in the other end portion in the longitudinal direction of the opto-electric hybrid board 1.

The first opening portion 14A intervenes between the light-emitting element 4A and the drive integrated circuit 5A.

The second opening portion 14B intervenes between the light-receiving element 4B and the impedance converting amplifier circuit 5B. The light-receiving element 4B and the impedance converting amplifier circuit 5B are disposed in the other end portion in the longitudinal direction of the opto-electric hybrid board 1.

While the illustrative embodiments of the present invention are provided in the above description, such is for illustrative purpose only and it is not to be construed as limiting in any manner Modification and variation of the present invention that will be obvious to those skilled in the art is to be covered by the following claims.

### INDUSTRIAL APPLICABILITY

The opto-electric hybrid board of the present invention is used for optics.
1 opto-electric hybrid board
2 optical waveguide
3 electric circuit board
4 optical element portion
5 driver element portion
10 metal supporting layer
14 opening portion
16A first terminal
16B second terminal
23 recess
24 notched opening portion

1. An opto-electric hybrid board comprising:
an optical waveguide; and
an electric circuit board disposed on a one-side surface in a thickness direction of the optical waveguide, the electric circuit board including
a first terminal disposed on a one-side surface in the thickness direction of the electric circuit board, the first terminal being for mounting an optical element portion, and
a second terminal disposed on the one-side surface in the thickness direction of the electric circuit board, the second terminal being for mounting a driver element portion separated from the optical element portion by an interval in a first direction, wherein
the electric circuit board includes a metal supporting layer that overlaps the first terminal and the second terminal when the electric circuit board is projected in the thickness direction, and
the metal supporting layer has a recess and/or a penetrating portion that are/is located between the first terminal and the second terminal when the metal supporting layer is projected in the thickness direction.

2. The opto-electric hybrid board according to claim 1, wherein the recess and/or the penetrating portion are/is longer than each of the optical element portion and the driver element portion in an orthogonal direction orthogonal to the thickness direction and the first direction.

3. The opto-electric hybrid board according to claim 1, wherein the recess and/or the penetrating portion are/is filled with a part of the optical waveguide.
